(19) United States
(12) Patent Application Publication
(10) Pub. No.: US 2025/0220979 A1
(43) Pub. Date: Jul. 3, 2025

(54) SEMICONDUCTOR DEVICE

(71) Applicant: Samsung Electronics Co., Ltd., Suwon-si (KR)

(72) Inventors: Dukhyun CHOE, Suwon-si (KR); Sangjun LEE, Suwon-si (KR); Seunggeol NAM, Suwon-si (KR); Eunha LEE, Suwon-si (KR); Hyangsook LEE, Suwon-si (KR)

(73) Assignee: Samsung Electronics Co., Ltd., Suwon-si (KR)

(21) Appl. No.: 19/008,189

(22) Filed: Jan. 2, 2025

(30) Foreign Application Priority Data
Jan. 3, 2024 (KR) 10-2024-0000904
Dec. 9, 2024 (KR) 10-2024-0181949

(51) Int. Cl. H10D 30/69; H10D 62/40; H10D 64/27; H10D 64/68

(52) U.S. Cl. CPC H10D 30/701; H10D 62/40; H10D 64/514; H10D 64/689

(57) ABSTRACT

A semiconductor device is provided. The semiconductor device includes a semiconductor layer, an electrode disposed on the semiconductor layer, and a ferroelectric layer arranged between the semiconductor layer and the electrode, the ferroelectric layer including an orthorhombic crystal structure of an oIV phase (space group: Pmn21) and doped with a dopant having an ionic radius larger than that of a hafnium ion or an oxygen ion at 2.8 at % or more.

### CROSS-REFERENCE TO RELATED APPLICATION

This application is based on and claims priority under 35 U.S.C. § 119 to Korean Patent Application Nos. 10-2024-0000904, filed on Jan. 3, 2024, and 10-2024-0181949, filed on Dec. 9, 2024 in the Korean Intellectual Property Office, the disclosures of which are incorporated by reference herein in their entirety.

### BACKGROUND

### 1. Field

The disclosure relates to a semiconductor device, and more particularly, to a semiconductor device including a ferroelectric layer.

### 2. Description of the Related Art

Ferroelectrics are materials that have ferroelectricity, which maintains spontaneous polarization by aligning the internal electric dipole moments even after an external electric field is no longer being applied. In other words, ferroelectrics are materials in which the polarization value (or electric field) remains semi-permanently within the material even when a certain voltage is applied and then the voltage is returned to 0 V. Research has been conducted to apply these ferroelectric properties to semiconductor devices (D) to improve the performance of the devices. For example, research has been conducted from the past to apply, to memory devices, the characteristic of ferroelectric polarization values exhibiting hysteresis with respect to voltage changes.

In addition, recent research results have been published on the possibility that ferroelectrics may have negative capacitance in a specific region, and when the ferroelectrics are applied to transistors, a subthreshold swing value may be lowered to below 60 mV/dec, which was the theoretical limit of existing silicon-based transistors. As a result, research to utilize ferroelectrics in low-power semiconductor devices (D) is being conducted.

### SUMMARY

Provided is a semiconductor device having a high polarization value and a low polarization switching energy barrier.

Provided is a semiconductor device including a ferroelectric layer in which an orthorhombic crystal structure of an oIV phase (space group: Pmn21) is stably maintained.

Additional aspects will be set forth in part in the description which follows and, in part, will be apparent from the description, or may be learned by practice of the presented embodiments of the disclosure.

According to an aspect of the disclosure, a semiconductor device includes a semiconductor layer, an electrode on the semiconductor layer, and a ferroelectric layer the substrate 100 of FIG. 15, the ferroelectric layer including an orthorhombic crystal structure of an oIV phase (space group: Pmn21) and doped with a dopant at 2.8 at % or more, the dopant having an ionic radius larger than that of at least one of a hafnium ion or an oxygen ion.

The dopant may expand a lattice volume of the orthorhombic crystal structure of the oIV phase (space group: Pmn21).

Also, the dopant may include elements having a same ionic valence as the oxygen ion and a larger ionic radius than the oxygen ion.

Also, the dopant may include at least one of sulfur(S), selenium (Se), or tellurium (Te).

Also, the dopant may include an element having a same ionic valence as the hafnium ion and a larger ionic radius than the hafnium ion.

Also, the dopant may include cerium (Ce).

Also, the dopant may be within a range of 2.8 at % to 10 at %.

Also, the orthorhombic crystal structure of the oIV phase (space group: Pmn21) has an interplanar distance (d-spacing) of 3.05 Å or more in an out-of-plane direction to a surface of the semiconductor layer.

In addition, the ferroelectric layer may further include an orthorhombic crystal structure of an oIII phase.

Also, among the orthorhombic crystal structure of the oIV phase (space group: Pmn21), an interplanar distance (d-spacing) in an out-of-plane direction to a surface of the semiconductor layer may be larger than an interplanar distance (d-spacing) of an orthorhombic crystal structure of an oIII phase.

In addition, among a crystal structure of the ferroelectric layer, the orthorhombic crystal structure of the oIV phase (space group: Pmn21) may be dominant.

Also, among a crystal structure of the ferroelectric layer, the orthorhombic crystal structure of the oIV phase (space group: Pmn21) may account for 50% or more.

In addition, the ferroelectric layer may include at least one of hafnium oxide or hafnium zirconium oxide.

Also, a thickness of the ferroelectric layer may be 2 nm or more.

In addition, a thickness of the ferroelectric layer may be 10 nm or less.

Also, the semiconductor layer may include a channel overlapping the ferroelectric layer in a thickness direction of the ferroelectric layer, and a source region and a drain region spaced apart from each other with the channel therebetween.

The semiconductor device may further include a paraelectric layer between the ferroelectric layer and the semiconductor layer.

Also, the paraelectric layer may include at least one of aluminum oxide (Al₂O₃), lanthanum oxide (La₂O₃), yttrium oxide (Y₂O₃), and silicon oxide (SiO₂).

In addition, the semiconductor device may further include a conductive material between the semiconductor layer and the ferroelectric layer.

Also, the semiconductor layer may include at least one component of a transistor.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram showing a semiconductor device according to at least one embodiment;

FIG. 2 is a schematic diagram showing a crystal direction of hafnium oxide (HfO₂) having an orthorhombic crystal structure of an oIII phase;

FIG. 3 is a schematic diagram showing a crystal direction of HfO₂ having an orthorhombic crystal structure of an oIII phase that is preferentially grown in a specific direction;

FIG. 4 is a schematic diagram showing a crystal direction of HfO₂ having an orthorhombic crystal structure of an oIV phase that is preferentially grown in a specific direction;

FIG. 5 is a diagram showing results of crystallizing HfO₂ grown in different thicknesses, according to at least one embodiment;

FIG. 6 is a graph showing a result of measuring an interplanar distance according to a thickness of a ferroelectric layer, according to at least one embodiment;

FIG. 7 is a graph showing internal energy by phase according to an interplanar distance, according to at least one embodiment;

FIG. 8 is a graph showing expansion of lattice volume according to the content of a dopant in a ferroelectric layer, according to at least one embodiment;

FIG. 9 is a graph showing an expansion ratio of lattice volume according to the content of cerium (Ce) in a ferroelectric layer, according to at least one embodiment;

FIG. 10 is a schematic diagram showing a field effect transistor according to at least one embodiment;

FIG. 11 is a schematic diagram showing a field effect transistor according to at least one embodiment;

FIG. 12 is a schematic diagram showing a semiconductor device including a paraelectric layer, according to at least one embodiment;

FIG. 13 is a schematic cross-sectional view showing a structure of a memory device according to at least one embodiment;

FIG. 14 is a diagram showing an electronic device (capacitor) according to at least one embodiment;

FIG. 15 is a schematic diagram showing an electronic device according to at least one embodiment;

FIG. 16 is a diagram showing an electronic device according to another embodiment;

FIG. 17 is a cross-sectional view of the electronic device taken along line A-A′ of FIG. 16;

FIG. 18 is a conceptual diagram showing a device architecture that may be applied to a device, according to at least one embodiment; and

FIG. 19 is a conceptual diagram schematically showing a device architecture that may be applied to a device, according to at least one embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list.

Hereafter, embodiments will be described more fully with reference to the accompanying drawings. In the drawings, like reference numerals refer to like elements, and in the drawings, sizes of constituent elements may be exaggerated for clarity and convenience of explanation. The following embodiments described below are merely illustrative, and various modifications may be possible from the embodiments. Additionally, when the terms “about” or “substantially” are used in this specification in connection with a numerical value and/or geometric terms, it is intended that the associated numerical value includes a manufacturing tolerance (e.g., +10%) around the stated numerical value. Further, regardless of whether numerical values and/or geometric terms are modified as “about” or “substantially,” it will be understood that these values should be construed as including a manufacturing or operational tolerance (e.g., +10%) around the stated numerical values and/or geometry. Further, when referring to as “within a range of” “C to D”, this means C inclusive to D inclusive unless otherwise specified.

Hereinafter, when a position of an element is described using an expression “above” or “on”, the position of the element may include not only the element being “immediately on/under/left/right in a contact manner” but also being “on/under/left/right in a non-contact manner”. For example, such directional terms, such as “above”, “below”, and/or similar directional terms, are intended to encompass different orientations of the device in use or operation in addition to the orientation depicted in the figures, and that the device may be otherwise oriented (rotated 90 degrees or at other orientations) and the spatially relative terms used herein interpreted accordingly. Singular forms include the plural forms unless the context clearly indicates otherwise. When a part “comprises” or “includes” an element in the specification, unless otherwise defined, it is not excluding other elements but may further include other elements.

The term “above” and similar directional terms may be applied to both singular and plural. With respect to operations that constitute a method, the operations may be performed in any appropriate sequence unless the sequence of operations is clearly described or unless the context clearly indicates otherwise.

Also, in the specification, the term “units” or “ . . . modules” denoting units or modules that are configured to process at least one function or operation, and may be realized by processing circuitry, such as hardware, software, or a combination of hardware and software. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components (such as at least one of transistors, resistors, capacitors, etc.), and/or electronic circuits including said components.

In addition, the connecting lines or connecting members between the components shown in the drawings are merely illustrative of functional connections and/or physical or circuit connections. In a practical device, the connections between the components may be represented by various functional connections, physical connections, or circuit connections that may be replaced or added.

Although the terms ‘first’, ‘second’, etc. may be used herein to describe various constituent elements, these constituent elements should not be limited by these terms. These terms are only used to distinguish one constituent element from another.

All examples or example terms (for example, etc.) are simply used to explain in detail the technical scope of the disclosure, and thus, the scope of the disclosure is not limited by the examples or the example terms as long as it is not defined by the claims.

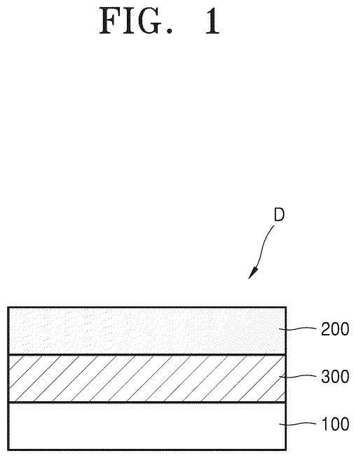

FIG. 1 is a diagram showing a semiconductor device D according to at least one embodiment.

Referring to FIG. 1, the semiconductor device D according to at least one embodiment includes a semiconductor layer 100, an electrode 200 on the semiconductor layer 100, and a ferroelectric layer 300 between the semiconductor layer 100 and the electrode 200 and including an orthorhombic crystal structure of oIV phase (space group: Pmn21).

The semiconductor layer 100 may include an elemental (e.g., Group IV) semiconductor, a compound semiconductor (e.g., a Group III-V compound semiconductor and/or a Group II-VI compound semiconductor), a two-dimensional semiconductor, an oxide semiconductor, and/or the like. For example, the semiconductor layer 100 may include, e.g., Si, Ge, SiGe, MoS₂, WSc₂, graphene, IGZO, IWO, ZnSnO, a combination thereof, and/or the like.

The electrode 200 may be arranged on the semiconductor layer 100. The electrode 200 may include a zero-bandgap material and/or a semiconductor material doped to have a conductivity corresponding to a zero-bandgap material. For example, in at least some embodiments, the electrode 200 may include at least one selected from metal, metal nitride, metal carbide, polysilicon, and/or a combination thereof.

The ferroelectric layer 300, including an orthorhombic crystal structure of oIV phase (space group: Pmn21), is between the semiconductor layer 100 and the electrode 200 and may be configured to electrically isolate the semiconductor layer 100 from the electrode 200. The ferroelectric layer 300 may be formed such that, after depositing an amorphous layer including a fluorite-based material, the deposition is heat-treated to crystallize the fluorite-based material.

For example, the amorphous layer may be formed by using a conventional method known in the art. For example, atomic layer deposition (ALD), chemical vapor deposition (CVD), physical vapor deposition (PVD), or sputtering may be used to form the amorphous layer. Among these, the atomic layer deposition ALD method has the advantage of being able to form a uniform layer in atomic units and may be performed at a relatively low temperature.

When forming an amorphous layer through the ALD method, a hafnium source, a zirconium source, and an oxygen source may be or include corresponding precursors. For example, as a hafnium source, at least one selected from hafnium (IV) tert-butoxide (Hf(O-t-Bu)₄), tetrakis ethyl methyl amino hafnium (TEMAH), tetrakis di-methyl amino hafnium (TDMAH), tetrakis di-ethyl amino hafnium (TDEAH), and/or a combination thereof may be used, but the disclosure is not limited thereto. In addition, as a zirconium source, at least one selected from Zr(O-t-Bu)₄, tetrakis ethyl methyl amino zirconium (TEMAZ), tetrakis di-methyl amino zirconium (TDMAZ), tetrakis di-ethyl amino zirconium (TDEAZ), and a combination thereof may be used, but the disclosure is not limited thereto. In addition, as an oxygen source, at least one selected from O₃, H₂O, O₂, N₂O, plasma, and a combination thereof may be used, but the disclosure is not limited thereto.

The amount of thermal budget by the heat treatment may be determined by considering the composition and thickness of the amorphous layer including the fluorite-based material. The heat treatment may be performed at a temperature of about 150° C. or higher and about 1100° C. or lower. For example, the heat treatment may be performed within a range of 150° C. to 1100° C. Additionally, in at least some embodiments, a rapid thermal processing (RTP) that may ramp up/ramp down at a relatively high speed, a laser heat treatment, etc. may be applied. The heat treatment may be performed for 1 nanosecond or higher, 1 microsecond or higher, 0.001 second or higher, 0.01 second or higher, 0.05 second or higher, 0.1 second or higher, 0.5 second or higher, 1 second or higher, 3 seconds or higher, or 5 seconds or higher, and for 10 minutes or lower, 5 minutes or lower, 1 minute or lower, or 30 seconds or lower, but the disclosure is not limited thereto. The atmosphere in which heat treatment is performed is not particularly limited. The heat treatment is configured to promote the growth of a ferroelectric phase crystalline structure in the amorphous layer, thereby converting the amorphous layer into the ferroelectric layer 300.

As noted above, ferroelectricity refers to a property in which internal electric dipole moments are aligned in a material to maintain a spontaneous polarization without any external electric field applied thereto. Therefore, even when a specific voltage is applied to a substance having such a property, i.e., ferroelectrics, and then the voltage is brought back to 0 V, polarization in the ferroelectrics may remain semi-permanently. Ferroelectricity is phase dependent, such that a material having a ferroelectric phase (e.g., a crystal structure lacking an inversion center (e.g., is non-centrosymmetric) as a dominant phase exhibits ferroelectricity, while a comparative material including the same (or similar composition) but lacking the ferroelectric phase lacks ferroelectricity. Accordingly, the ferroelectric layer 300 according to at least one embodiment may include an orthorhombic crystal structure of oIV phase (space group: Pmn21) (hereinafter, simply referred to as ‘oIV phase’). The ferroelectric layer 300 may include various crystal structures such as an orthorhombic crystal structure and a tetragonal crystal structure, and among the orthorhombic crystal structures, oI phase, oII phase, oIII phase, etc. may also be included. In at least one embodiment, the ferroelectric layer 300 may include the orthorhombic crystal structure of the oIV phase dominantly (largest ratio or upper ratio among all crystal structures). For example, the orthorhombic crystal structure of the oIV phase may be about 10% or more, 20% or more, 30% or more, 40% or more, 50% or more, and/or 90% or less, 80% or less, 70% or less, or 60% or less of the entire crystal structure. The distribution of the crystal structure may be confirmed by a method known in the art; for example, transmission electron microscopy (TEM), grazing incidence X-ray diffraction (GIXRD), etc. may be used.

When a fluorite-based material is first grown to a thickness of about 1.5 nm on a semiconductor layer 100 with a crystal direction (11x) (0≤x≤1) aligned in an out-of-plane direction to a surface of the semiconductor layer 100 and then heat-treated, the fluorite-based material may be crystallized into an orthorhombic crystal structure of the oIV phase. On the other hand, when a fluorite-based material with a thickness of about 3 nm is deposited on the semiconductor layer 100 and then laser heat-treated, the fluorite-based material may be crystallized into an orthorhombic crystal structure of the oIII phase (Pca21 space group) (hereinafter simply referred to as ‘oIII phase’).

Meanwhile, the crystal direction of the orthorhombic crystal structure of the oIII phase may be a random orientation or aligned in a specific direction.

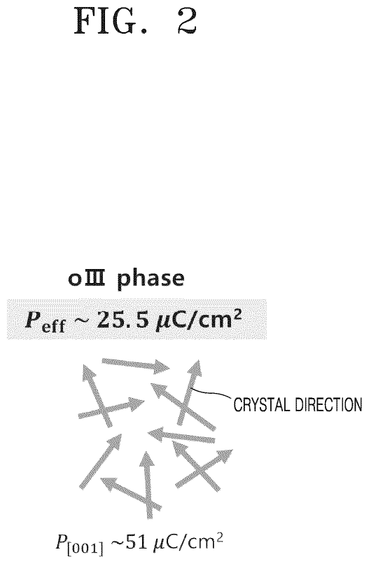

FIG. 2 is a schematic diagram showing a crystal direction of hafnium oxide (HfO₂) having an orthorhombic crystal structure of the oIII phase. As shown in FIG. 2, the growth direction of the hafnium oxide may be a random direction. The crystal direction with the largest polarization value of HfO₂ having an orthorhombic crystal structure of the oIII phase is (001), and the size is about 51 μC/cm². Because the crystal structures forming the ferroelectric layer 300 grow in a random direction without a clear direction, the polarization efficiency (Peff, effective polarization) in the out-of-plane direction of the semiconductor layer 100 may be approximately 25.5 μC/cm², which is 50% of the polarization value in the (001) crystal direction.

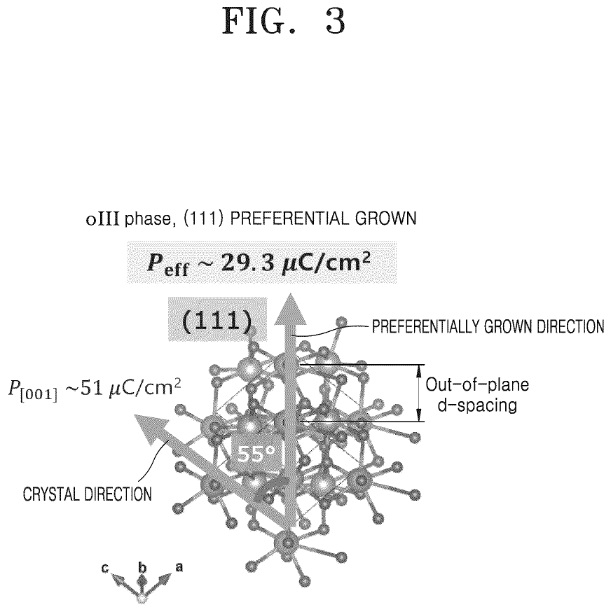

FIG. 3 is a schematic diagram showing a crystal direction of HfO₂ having an orthorhombic crystal structure of oIII phase, which is preferentially grown in a specific direction. As shown in FIG. 3, HfO₂ may have a preferential growth direction such that the (111) crystal direction may be aligned in the out-of-plane direction (hereinafter, also simply referred to as the ‘out-of-plane direction’) to a surface of the semiconductor layer 100. The crystal direction having the largest polarization value of HfO₂ having an orthorhombic crystal structure of oIII phase is (001), and the size is approximately 51 μC/cm². An angle between the (001) crystal direction and a growth direction (or out-of-plane direction) is approximately 55° C., and thus the polarization efficiency (Peff, effective polarization) in the out-of-plane direction may be approximately 29.3 μC/cm².

It may be confirmed that the polarization efficiency of the hafnium oxide grown preferentially in a specific direction is greater than that of the hafnium oxide grown in a random direction. However, the polarization efficiency of the hafnium oxide having the orthorhombic crystal structure of the oIII phase is still low as less than 30 μC/cm². In addition, a polarization switching energy barrier of the hafnium oxide having the orthorhombic crystal structure of the oIII phase is high at about 40 meV; therefore, an operating voltage would also be correspondingly high.

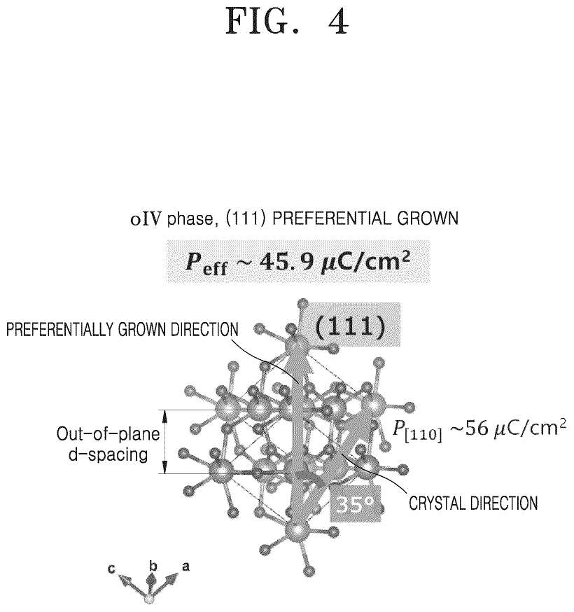

FIG. 4 is a schematic diagram showing a crystal direction of the HfO₂ having the orthorhombic crystal structure of the oIV phase grown preferentially in a specific direction. As shown in FIG. 4, the hafnium oxide may have a preferential growth direction so that the (111) crystal direction may be aligned in the out-of-plane direction. The crystal direction having the largest polarization value of the HfO₂ having the orthorhombic crystal structure of the oIV phase is (110), and the size is about 56 μC/cm². An angle between the (111) crystal direction and the out-of-plane direction (or preferred growth direction) is approximately 35°, and the polarization efficiency (Peff, effective polarization) in the out-of-plane direction is significantly increased to approximately 45.9 μC/cm².

It may be confirmed that the hafnium oxide with the orthorhombic crystal structure of the oIV phase and the preferred growth direction so that the (111) crystal direction is aligned to the out-of-plane direction has a polarization efficiency increased by approximately 80% or more than the hafnium oxide with the orthorhombic crystal structure of the oIII phase and grown in a random direction.

In addition, the polarization switching energy barrier of the hafnium oxide with the orthorhombic crystal structure of the oIV phase is approximately 8 meV, which is approximately 0.2 times (e.g., one-fifth) lower than that of the hafnium oxide with the orthorhombic crystal structure of the oIII phase. Therefore, the ferroelectric layer 300 having an orthorhombic crystal structure of oIV phase (space group: Pmn21) and the <11x>(0≤x≤1) crystal direction of which is aligned in the out-of-plane direction may have high polarization characteristics and a low polarization switching energy barrier.

The ferroelectric layer 300 may well maintain ferroelectricity by having a predetermined thickness according to the characteristics of the semiconductor element D. The thickness of the ferroelectric layer 300 may be 2 nm or more, 3 nm or more, 4 nm or more, and/or 10 nm or less, or 5 nm or less. For example, a DRAM semiconductor device may have a ferroelectric layer having a thickness of about 5 nm, and a NAND semiconductor device may have a ferroelectric layer having a thickness of about 10 nm.

The ferroelectric layer 300 may be formed by repeating a process of growing a fluorite-based amorphous layer having a predetermined thickness and then heat-treating the fluorite-based amorphous layer at least once. As the number of times the growth and heat-treating process is repeated increases, the phase of the ferroelectric layer 300 may change, and the phase may become unstable. Therefore, the ferroelectric layer 300 the orthorhombic crystal structure of the oIV phase is stably maintained with a small number of processes. Hereinafter, descriptions are mainly focused on phases and the crystal structure and crystal direction are omitted, but the crystal structure and crystal direction are the same as described above.

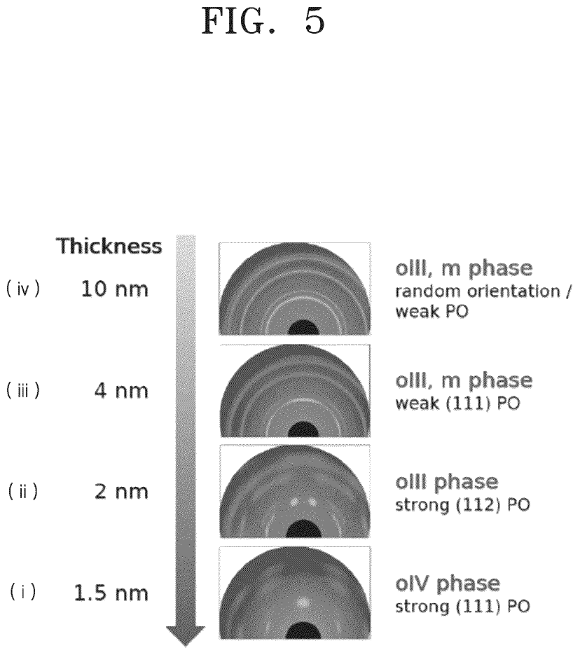

FIG. 5 is a diagram showing results of crystallizing hafnium oxide grown in different thicknesses, according to at least one embodiment.

Amorphous hafnium oxides with thicknesses of about 1.5 nm, about 2 nm, about 4 nm, and about 10 nm, respectively, were first grown on the semiconductor layer 100 so that the (111) crystal direction is aligned to the out-of-plane direction, and then crystallized by laser annealing at about 1000° C. In FIG. 5, (i) is an X-ray diffraction (XRD) pattern of crystallized hafnium oxide having a thickness of about 1.5 nm, (ii) is an XRD pattern of crystallized hafnium oxide having a thickness of about 2 nm, (iii) is an XRD pattern of crystallized hafnium oxide having a thickness of about 4 nm, and (iv) is an XRD pattern of crystallized hafnium oxide having a thickness of about 10 nm.

Referring to the drawing, it may be confirmed that a peak of a (111) plane and a peak of a (1-11) plane are at different positions in the hafnium oxide having a thickness of about 1.5 nm. The peak of the (1-11) plane is located at a higher angle than the peak of the (111) plane. The fact that the peak of the (111) plane and the peak of the (1-11) plane are at different positions may denote that the crystallized hafnium oxide has an oIV phase.

It may be confirmed that a peak of a (112) plane strongly exists in the hafnium oxide having a thickness of about 2 nm, the peak of the (111) plane weakly exists in the hafnium oxide having a thickness of about 4 nm, and the peak does not exist in the hafnium oxide having a thickness of about 10 nm. It may be confirmed that the thicker the hafnium oxide, the higher the probability that it has an oIII phase, and the crystal direction also becomes random.

From the results of FIG. 5, it may be confirmed that it is difficult to form the ferroelectric layer 300 including an orthorhombic crystal structure of the oIV phase with a thickness of 2 nm or more in one process. In order to form the ferroelectric layer 300 including an orthorhombic crystal structure of the oIV phase with a thickness of 2 nm or more, an amorphous hafnium oxide having a thickness of about 1.5 nm may be grown and then a heat treatment process may be repeated multiple times. As the number of processes of the ferroelectric layer 300 increases, the orthorhombic crystal structure of the oIV phase may change to another phase, which may lower the polarization characteristics and increase the polarization switching energy barrier. Thereby, the ferroelectric layer 300 according to at least one embodiment stably maintains the orthorhombic crystal structure of the oIV phase.

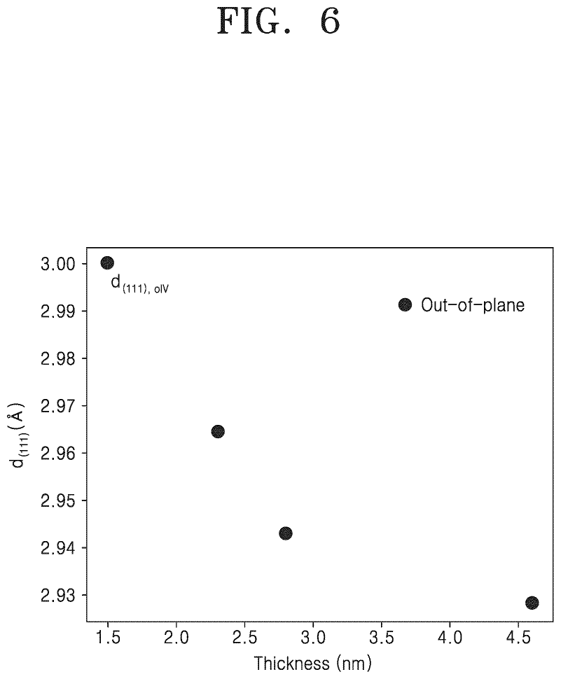

FIG. 6 is a result of measuring an interplanar distance according to a thickness of the ferroelectric layer, according to at least one embodiment. On the semiconductor layer 100, amorphous hafnium oxides having a thickness of about 1.5 nm, about 2.3 nm, about 2.7 nm, and about 4.6 nm were first grown so that the (111) crystal direction is aligned in the out-of-plane direction, and then crystallized by laser annealing at about 1000° C. Here, the interplanar distance is the interplanar distance in the out-of-plane direction to a surface of the semiconductor layer 100.

Referring to FIG. 6, it may be confirmed that the interplanar distance of the hafnium oxide having a thickness of about 1.5 nm is about 3 A, and the interplanar distance of the hafnium oxide having a thickness of 2.0 nm or more is 2.97 A or less. As described with reference to FIG. 5, the hafnium oxide having a thickness of about 1.5 nm has an orthorhombic crystal structure of the oIV phase, while the hafnium oxide having a thickness of about 2.0 nm or more has an orthorhombic crystal structure of the oIII phase. It may also be confirmed that the interplanar distance of the orthorhombic crystal structure of the oIV phase is greater than the interplanar distance of the orthorhombic crystal structure of the oIII phase. Therefore, because the interplanar distance in the out-of-plane direction of the ferroelectric layer 300 is greater than a certain value, the orthorhombic crystal structure of the oIV phase included in the ferroelectric layer 300 may be stably maintained.

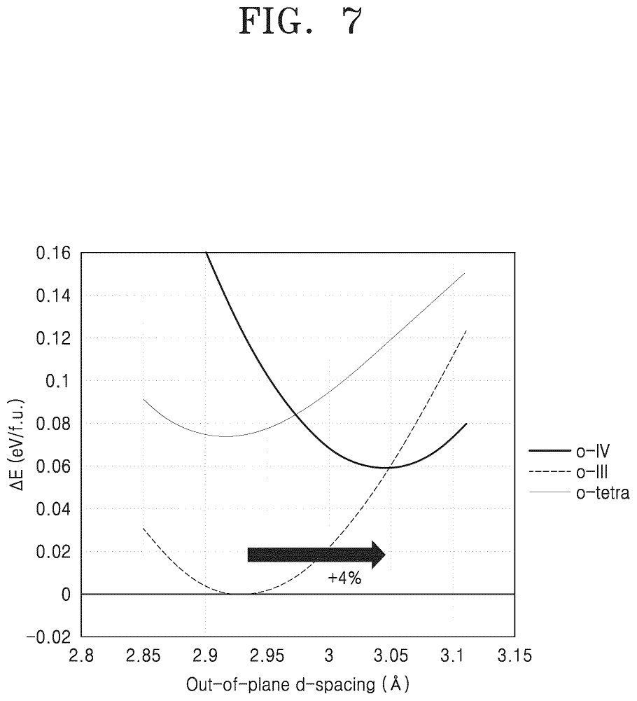

FIG. 7 is a graph showing the internal energy by phase according to the interplanar distance, according to at least one embodiment. The internal energy by phase of FIG. 7 is the internal energy by interplanar distance in the out-of-plane direction when the (111) direction is first grown as the out-of-plane direction through first-principle calculation. Referring to FIG. 7, the hafnium oxide having the oIII phase has the lowest internal energy when the interplanar distance is about 2.93 Å. The hafnium oxide having the oIV phase has the lowest internal energy when the interplanar distance is about 3.05 A. That is, the hafnium oxide having an interplanar distance in the out-of-plane direction of less than 3.05 Å is stable when existing in the oIII phase, and hafnium oxide having an interplanar distance in the out-of-plane direction of 3.05 Å or more is stable when existing in the oIV phase. In other words, the hafnium oxide having an interplanar distance in the out-of-plane direction of less than 3.05 Å may be dominated by the oIII phase, and the hafnium oxide having an interplanar distance in the out-of-plane direction of 3.05 Å or more may be dominated by the oIV phase. Therefore, in order to form hafnium oxide in which the oIV phase is dominant, the interplanar distance in the out-of-plane direction, in at least some embodiments, is 3.05 Å or more.

The ferroelectric layer 300 according to at least one embodiment may further include a dopant that may expand the interplanar distance or lattice volume of the crystal structure so that the orthorhombic crystal structure of the oIV phase is stably maintained. Here, the interplanar distance may denote the interplanar distance in the vertical direction with respect to the surface of the semiconductor layer 100.

The dopant doped in the ferroelectric layer 300 according to at least one embodiment may include at least one element having an ionic radius larger than that of an oxygen ion. The dopant may be an element having the same ion valence (or oxidation state) as the oxygen ion and having a larger ionic radius than the oxygen ion. For example, the dopant mentioned above may include at least one of S, Se, and/or Te.

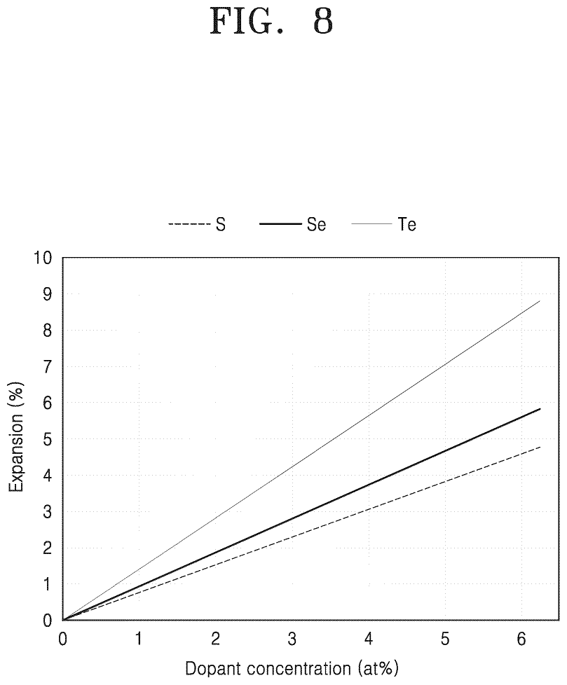

FIG. 8 is a graph showing expansion of the lattice volume according to the content of the dopant in the ferroelectric layer 300, according to at least one embodiment. Here, the content (at) of the dopant may denote a ratio of the dopant to a metal included in the ferroelectric layer 300. The expansion ratio of FIG. 8 is based on the first-principle calculation. It may be confirmed that the expansion ratio is about 4% when Te, Se, and S are doped at about 2.8%, about 4.3%, and about 5.3%, respectively. Here, 4% is a ratio of the lowest internal energy of the hafnium oxide having the oIV phase with respect to the lowest internal energy of the hafnium oxide having the oIII phase in FIG. 7. When Te, Se, and S are each doped at about 2.8 at %, about 4.3 at %, and about 5.3 at % or more, the interplanar distance in the out-of-plane direction of the ferroelectric layer 300 may be 3.05 Å or more, and the ferroelectric layer 300 may stably maintain the oIV phase.

Referring to FIG. 8, it may be confirmed that the larger the ionic radius of the dopant, the more the lattice of the ferroelectric layer 300 may be expanded even with a small content. When the dopant is doped at about 3.0 at % or more, the ferroelectric layer 300 may stably maintain the oIV phase.

Alternatively, the dopant doped into the ferroelectric according to at least one embodiment may include at least one element having an ionic radius greater than that of hafnium ion. The dopant may be an element having the same ionic valence as the hafnium ion and a greater ionic radius than the hafnium ion. For example, the dopant may include cerium (Ce). Alternatively, the dopant may be an element having a different ion valence from the hafnium ion but a larger ionic radius than the hafnium ion. For example, the dopant may further include at least one of La, Sm, Gd, Tb, Dy, Y, Er, Tm, TI, Yb, Lu, Au, In, Sb, and Sc having an ion valence of +3.

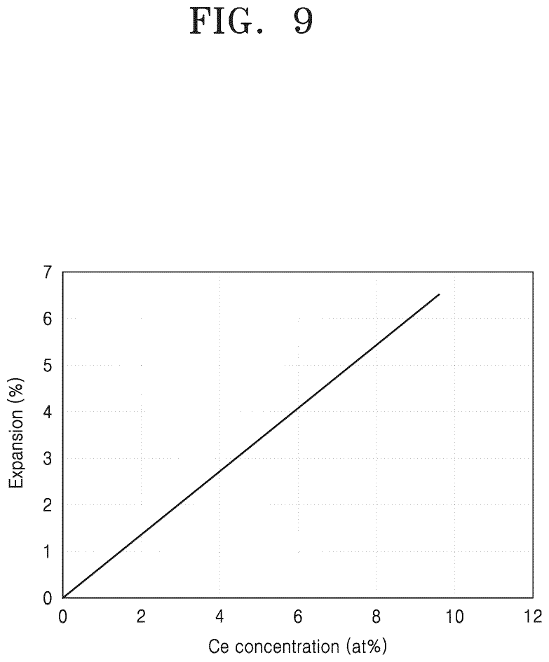

FIG. 9 is a graph showing an expansion ratio of a lattice volume according to the content of Ce in the ferroelectric layer 300, according to at least one embodiment. The expansion ratio of FIG. 9 is based on the first-principle calculation. Referring to FIG. 9, it may be confirmed that when Ce is doped at about 6 at %, the lattice expansion ratio of the ferroelectric is about 4%. Here, the lattice expansion ratio of 4 at % is the ratio of the lowest internal energy of the hafnium oxide having the oIV phase to the lowest internal energy of the hafnium oxide having the oIII phase. When Ce is doped at about 6 at % or more, the interplanar distance in the out-of-plane direction of the ferroelectric layer 300 may be 3.05 A or more, and it may be expected that the ferroelectric layer 300 may stably maintain the oIV phase.

When the ferroelectric layer 300 is formed with a hafnium-based oxide by adding the dopant described above, the ferroelectric layer 300 having the oIV phase may be formed even at a thickness exceeding 1.5 nm, e.g., a thickness of about 2 nm or more. As the content of the dopant increases, the thickness of the ferroelectric layer 300 having the oIV phase formed in one process may be increased. However, when the doping content of the dopant becomes too large, the characteristics of the ferroelectric layer 300 may be changed, and therefore, the content of the dopant may also be 10 at % or less.

Based on first-principle calculations, the interplanar distance in the out-of-plane direction of hafnium oxide having an orthorhombic crystal structure of oIV phase is approximately 3.05 Å or more, and the doping content of the dopant included in the ferroelectric layer 300 is approximately 2.8 at % or more. However, the interplanar distance in the out-of-plane direction of the ferroelectric layer 300 having the orthorhombic crystal structure of the oIV phase and the doping content of the dopant may be changed somewhat depending on the process conditions.

The preferred growth direction of the hafnium oxide is not limited to the direction in which the (111) crystal direction is aligned in the out-of-plane direction. The preferred growth direction of the hafnium oxide may be the direction in which the (11x) (0≤x≤1) crystal direction is aligned in the out-of-plane direction. An angle between the (111) crystal direction and the out-of-plane direction (or growth direction) is approximately 35°, and thus the polarization efficiency (Peff, effective polarization) in the out-of-plane direction is significantly increased to approximately 45.9 μC/cm². The angle between the (11x) (0≤x≤1) crystal direction and the out-of-plane direction may be less than 35°. Because the polarization value of the (110) crystal direction is the largest, when the (11x) (0≤x<1) crystal direction is aligned to the out-of-plane direction, the polarization efficiency may further be increased.

According to at least one embodiment, the semiconductor device D including a ferroelectric layer 300 disposed on the semiconductor layer 100 and including a crystal structure having an orthorhombic crystal structure of an oIV phase and a crystal direction aligned with (11x) (0≤x≤1) in the out-of-plane direction of the semiconductor layer 100 may have high polarization efficiency. The polarization efficiency of the ferroelectric layer 300 described above in the out-of-plane direction may be about 29 μC/cm² or more, 30 μC/cm² or more, 35 μC/cm² or more, and/or 55 μC/cm² or less, 50 μC/cm² or less, or 40 μC/cm² or less.

The ferroelectric layer 300 may include, in addition to hafnium oxide, hafnium nitride, hafnium zirconium oxide, and/or hafnium zirconium oxynitride as a base material, and may further include one or more dopant materials selected from S, Se, Te, Ce, and/or a combination thereof. The content of a dopant material may be about 2.5 at % or more, about 3 at % or more, about 5 at %, 10 at % or less, and/or 8 at % or less relative to a metal element of the base material. By adding a dopant capable of expanding the lattice volume, the orthorhombic crystal structure of the oIV phase may be stably maintained.

According to at least one embodiment, the semiconductor device described above may be a memory device or a non-memory device, and may be, for example, a field effect transistor, a capacitor, or any combination thereof, but is not limited thereto.

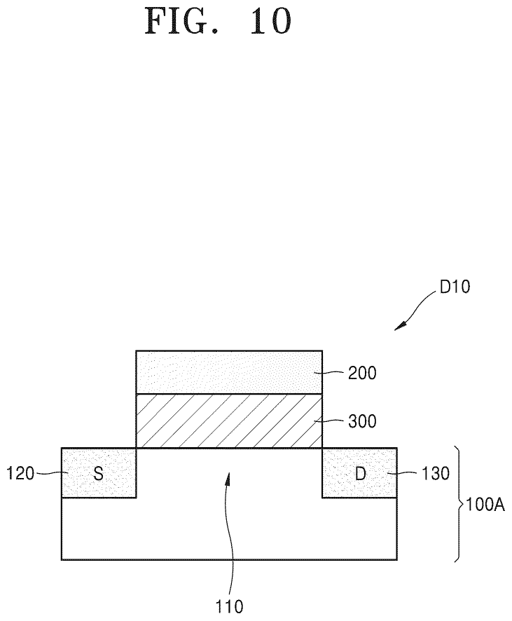

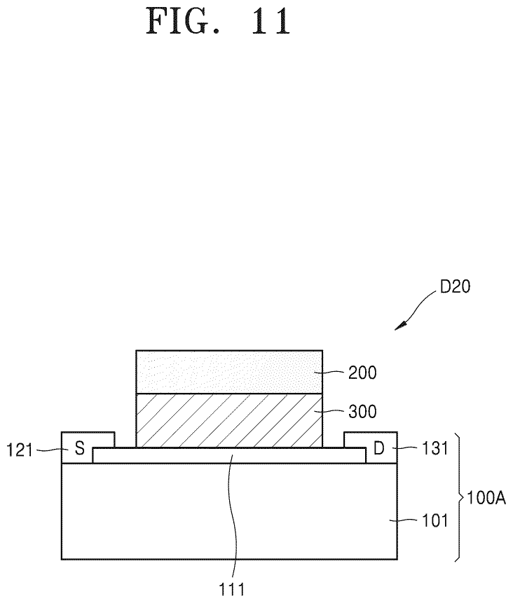

FIGS. 10 and 11 are schematic diagrams illustrating field effect transistors D10 and D20 according to at least one embodiment. Referring to FIGS. 10 and 11, the field effect transistor D10 includes a substrate 100A including a source 120 and a drain 130, an electrode 200 on the substrate 100A, and a ferroelectric layer 300 between the substrate 100A and the electrode 200, and the field effect transistor D20 includes a substrate 100A including a source 121 and a drain 131, an electrode 200 on the substrate 100A, and a ferroelectric layer 300 between the substrate 100A and the electrode 200. In the present cases, the electrode 200 may also be referred to as a gate electrode.

The substrate 100A may include a semiconductor material. For example, the substrate 100A may include at least one of Si, Ge, SiGe, a Group III-V semiconductor, etc., and may be used by being modified in various forms such as silicon on insulator (SOI).

The substrate 100A of the field effect transistor D10 may include the source 120 and the drain 130 and may include a channel 110 electrically connected to the source 120 and the drain 130. The source 120 may be electrically connected to or in contact with one end of the channel 110, and the drain 130 may be electrically connected to or in contact with the other end of the channels 110. The source 121 may be electrically connected to or in contact with one end of the channel 111, and the drain 131 may be electrically connected to or in contact with the other end of the channels 111.

Referring to FIG. 10, the channel 110 may be defined as a region between the source 120 and the drain 130 in the substrate 100A. In these cases, the substrate 100A may correspond to the semiconductor layer 100 of FIG. 1. The source 120 and the drain 130 may be formed by injecting impurities into different regions of the substrate 100A, and in this case, the source 120, the channel 110, and the drain 130 may correspond to the semiconductor layer 100 of FIG. 1.

Also, referring to FIG. 11, the channel 111 may be implemented as a material layer (thin film) separate from the substrate region 101. In these cases, the channel 111 may correspond to the semiconductor layer 100 of FIG. 1. The material composition of the channel 111 may vary. For example, the channel 111 may include at least one of not only a semiconductor material such as Si, Ge, SiGe, Group III-V semiconductor, etc., but also an oxide semiconductor, a nitride semiconductor, an oxynitride semiconductor, a two-dimensional material (2D material), a quantum dot, an organic semiconductor, and/or a combination thereof. For example, the oxide semiconductor may include InGaZnO, etc., the two-dimensional material may include a transition metal dichalcogenide (TMD) or graphene, and the quantum dot may include a colloidal quantum dot (CQD), a nanocrystal structure, etc. In addition, the source 121 and the drain 131 may include a conductive material, and may independently include, for example, a metal, a metal compound, or a conductive polymer.

The gate electrode 200 may be arranged on the substrate 100A and spaced apart from the substrate 100A and may be arranged to face the channels 110 and 111. The gate electrode 200 may correspond to the electrode 200 illustrated in FIG. 1.

The gate electrode 200 may have a conductivity of approximately 1 Mohm/square or less. The gate electrode 200 may include one or more selected from metal, metal nitride, metal carbide, polysilicon, and/or a combination thereof. For example, the metal may include aluminum (Al), tungsten (W), molybdenum (Mo), titanium (Ti), or tantalum (Ta), the metal nitride may include a titanium nitride (TiN) or a tantalum nitride (TaN), and the metal carbide may be a metal carbide doped with (or including) aluminum or silicon, specific examples of which include TiAlC, TaAlC, TiSiC, or TaSiC. The gate electrode 200 may have a structure in which multiple materials are stacked. For example, the gate electrode 200 may have a stack structure of a metal nitride layer/metal layer such as TiN/Al, or a stack structure of a metal nitride layer/metal carbide layer/metal layer such as TiN/TiAlC/W. The gate electrode 200 may include a TiN film or molybdenum (Mo), and the above example may be used in various modified forms.

The ferroelectric layer 300 may be arranged between the substrate 100A and the gate electrode 200. Specifically, the ferroelectric layer 300 may be formed on the channel 110 and 111.

The ferroelectric layer 300 may correspond to the ferroelectric layer 300 described with reference to FIG. 1. The ferroelectric layer 300 includes an orthorhombic crystal structure of oIV phase (space group: Pmn21) and may be doped with a dopant having an ionic radius greater than that of a hafnium ion or an oxygen ion. The dopant may expand a lattice volume of the orthorhombic crystal structure of the oIV phase (space group: Pmn21). The dopant may include an element having the same ion valence as an oxygen ion and a larger ionic radius than the oxygen ion, or an element having the same ion valence as hafnium ion and a larger ionic radius than the hafnium ion. For example, the dopant may include at least one of S, Se, Te, and Ce. The doping content of the dopant may be about 2.5 at % or more, about 2.8 at % or more, about 4 at % or more, about 6 at % or more, about 8 at % or less, or about 10 at % or less.

Among the ferroelectric layer 300, the orthorhombic crystal structure of the oIV phase (space group: Pmn21) may have an interplanar distance (d-spacing) of 3.05 Å or more in the out-of-plane direction to a surface of the semiconductor layer 100. When the ferroelectric layer 300 further includes an orthorhombic crystal structure of the oIII phase, the orthorhombic crystal structure of the oIII phase may have an interplanar distance (d-spacing) of less than 3.0 Å in the out-of-plane direction to the surface of the semiconductor layer 100. In the ferroelectric layer 300, the orthorhombic crystal structure of the oIV phase (space group: Pmn21) may be dominant. Among the ferroelectric layer 300, the orthorhombic crystal structure of the oIV phase (space group: Pmn21) may account for 50% or more.

The ferroelectric layer 300 may include at least one of hafnium oxide and hafnium zirconium oxide as a base material and may be doped with the dopant described above. A thickness of the ferroelectric layer 300 may be 2 nm or more, 3 nm or more, 5 nm or more, or 10 nm or less.

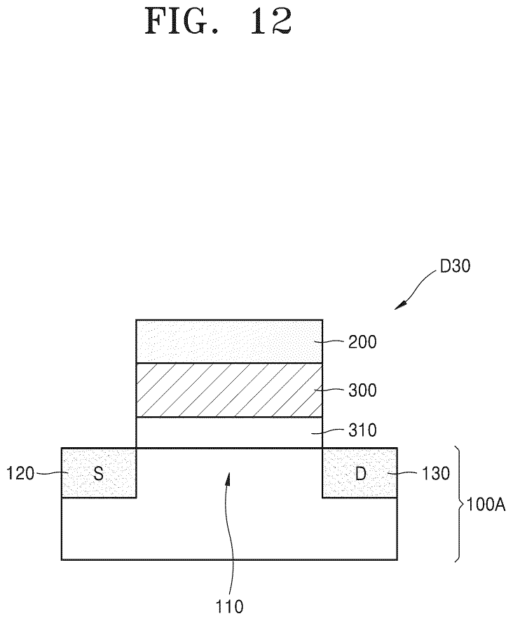

FIG. 12 is a schematic diagram showing a semiconductor device D30 (a field effect transistor) including a paraelectric layer 310, according to at least one embodiment. Comparing FIG. 10 and FIG. 12, the semiconductor device D30 of FIG. 12 may further include the paraelectric layer 310 between the channel 110 and the ferroelectric layer 300. Since like reference numerals refer to like elements in the present disclosure, repeat descriptions of the substrate 100A, the gate electrode 200, and the ferroelectric layer 300 is omitted for brevity and conciseness.

The paraelectric layer 310 may be configured to suppress or and/prevent electrical leakage. A thickness of the paraelectric layer 310 may be 0.1 nm or more, 0.3 nm or more, or 0.5 nm or more, and/or 5 nm or less, 4 nm or less, 3 nm or less, 2 nm or less, or 1 nm or less. The paraelectric layer 310 may include a paraelectric material or a high-k dielectric material, and may include silicon oxide, silicon nitride, aluminum oxide, hafnium oxide, zirconium oxide, etc., or a two-dimensional insulator (2D insulator) such as hexagonal boron nitride (h-BN). For example, the paraelectric layer 310 may include SiO₂, silicon nitride (SiNₓ), etc. In addition, the paraelectric layer 310 may include hafnium oxide (HfO₂), hafnium silicon oxide (HfSiO₄), lanthanum oxide (La₂O₃), lanthanum aluminum oxide (LaAlO₃), zirconium oxide (ZrO₂), zirconium silicon oxide (ZrSiO₄), tantalum oxide (Ta₂O₅), titanium oxide (TiO₂), strontium titanium oxide (SrTiO₃), yttrium oxide (Y₂O₃), aluminum oxide (Al₂O₃), red scandium tantalum oxide (PbSc_{0.5}Ta_{0.5}O₃), red zinc niobate (PbZnNbO₃), etc. Additionally, the ferroelectric layer 300 may include a metal nitride such as aluminum oxynitride (AlON), zirconium oxynitride (ZrON), hafnium oxynitride (HfON), lanthanum oxynitride (LaON), yttrium oxynitride (YON), etc., a silicate such as ZrSiON, HfSiON, YSiON, LaSiON, etc., or an aluminate such as ZrAlON, HfAlON, etc.

The field effect transistor may be implemented in various forms such as 2-dimension, 3-dimension, etc. For example, the field effect transistor may be a 1-gate on channel form such as a planar-FET, a 3-gate on channel form such as a Fin-FET, or a 4-gate on channel form such as a Gate-all-around-FET.

The semiconductor devices D, D10, D20, and D30 described above may be applied to various electronic devices, and, for example, may be applied as individual memory cells in a memory device. The memory device may have a 3-dimensional structure, a vertical structure, etc., and, for example, may have a vertical NAND (VNAND) structure.

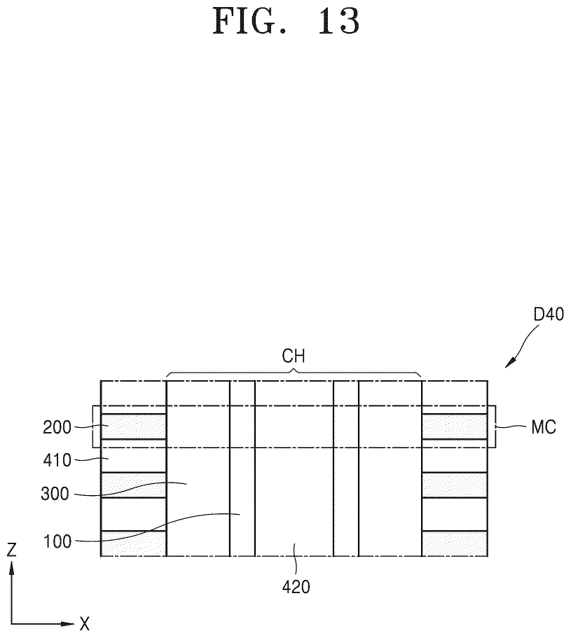

FIG. 13 is a schematic cross-sectional view showing a structure of a memory device D40 according to at least one embodiment.

The memory device D40 includes a plurality of memory cells MC. The plurality of memory cells MC may be repeatedly arranged in a first direction (Z direction). Each memory cell may include a gate electrode 200, a ferroelectric layer 300, and a semiconductor layer 100.

Specifically, a plurality of gate electrodes 200 and a plurality of spacers 410 may be alternately arranged in the first direction (e.g., the Z direction). Each of the plurality of gate electrodes 200 and the plurality of spacers 410 are connected to one of a word line (not shown) and a string selection line (not shown).

A channel hole CH is provided, wherein the channel hole CH vertically penetrates the plurality of gate electrodes 200 and the plurality of spacers 410 that are alternately arranged. The channel hole CH may include a plurality of layers. The channel hole CH may include a pillar 420 extending in the first direction, the semiconductor layer 100 surrounding a side surface of the pillar 420, and the ferroelectric layer 300 surrounding a side surface of the semiconductor layer 100. The gate electrode 200, the ferroelectric layer 300, and the semiconductor layer 100 of FIG. 13 may correspond to the electrode 200, the ferroelectric layer 300, and the semiconductor layer 100 described with reference to FIG. 1, respectively.

The pillar 420 may include silicon oxide. One end of the semiconductor layer 100 may be in contact with a common source region, and the other end of the semiconductor layer 100 may be in contact with a drain (not shown).

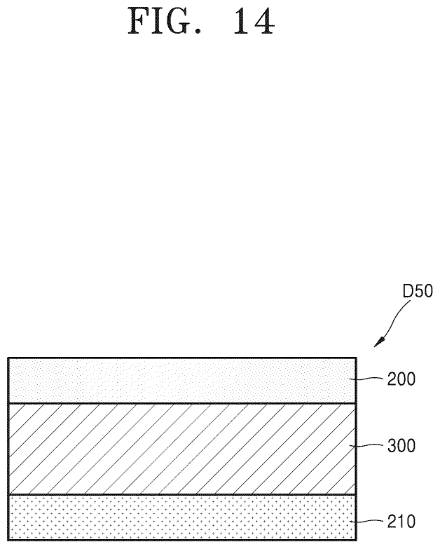

FIG. 14 illustrates an electronic device (capacitor) D50 according to at least one embodiment.

Referring to FIG. 14, the electronic device D50 includes a lower electrode 210, an upper electrode 200 spaced apart from the lower electrode 210, and a ferroelectric layer 300 between the lower electrode 210 and the upper electrode 200. Here, the ferroelectric layer 300 corresponds to the ferroelectric layer 300 described with reference to FIG. 1, and a detailed description is omitted.

The lower electrode 210 may be placed on a substrate (not shown). The substrate may be a part of a structure supporting the capacitor, or a part of a component connected to the capacitor. The substrate may correspond to the semiconductor layer 100 described with reference to FIG. 1. The substrate may include a semiconductor material pattern, an insulating material pattern, and/or a conductive material pattern. The substrate may include a semiconductor material, for example, silicon (Si), germanium (Ge), silicon germanium (SiGe), silicon carbide (SiC), gallium arsenide (GaAs), indium arsenide (InAs), indium phosphide (InP), and/or an insulating material, such as silicon oxide, silicon nitride, or silicon oxynitride.

The upper electrode 200 may be arranged to be spaced apart from and face the lower electrode 210. The upper electrode 200 may correspond to the electrode 200 described with reference to FIG. 1. The lower electrode 210 and the upper electrode 200 may each include a metal, a conductive metal nitride, a conductive metal oxide, or any combination thereof. Here, the metal may include, for example, ruthenium (Ru), titanium (Ti), tantalum (Ta), niobium (Nb), iridium (Ir), molybdenum (Mo), tungsten (W), platinum (Pt), etc. The conductive metal nitride may include, for example, TiN, TaN, niobium nitride (NbN), molybdenum nitride (MoN), cobalt nitride (CoN), or tungsten nitride (WN). The conductive metal oxide may include, for example, platinum oxide (PtO), iridium oxide (IrO₂), ruthenium oxide (RuO₂), strontium ruthenium oxide (SrRuO₃), barium strontium ruthenium oxide ((Ba,Sr)RuO₃), calcium ruthenium oxide (CaRuO₃), or lanthanum strontium cobalt oxide ((La,Sr)CoO₃).

The lower electrode 210 and the upper electrode 200 may each have a single material layer or a stack structure of multiple material layers. For example, the lower electrode 210 and the upper electrode 200 may each be a single layer of TiN or a single layer of NbN. Alternatively, the lower electrode 210 and the upper electrode 200 may each have a stack structure including a first electrode layer including TiN and a second electrode layer including NbN.

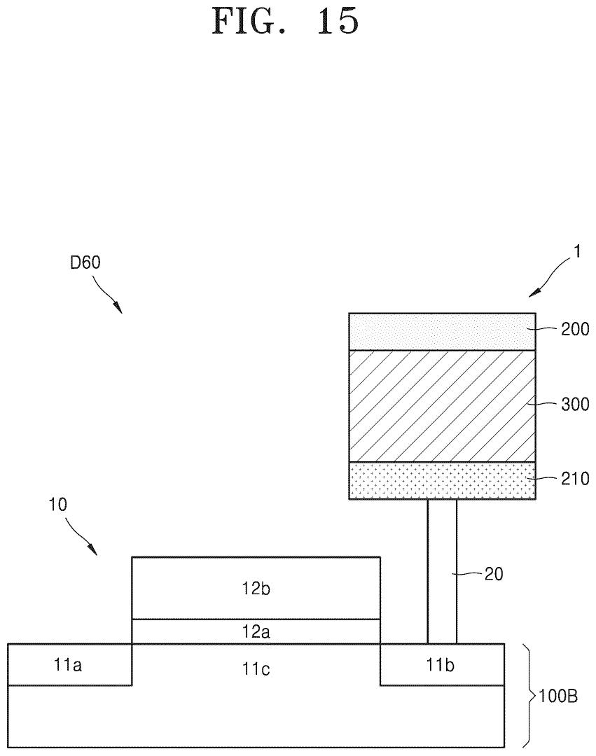

FIG. 15 is a schematic diagram illustrating an electronic device D60 according to at least one embodiment.

Referring to FIG. 15, the electronic device D60 may include a structure in which a capacitor 1 and a field effect transistor 10 are electrically connected by a contact 20. The capacitor 1 includes a lower electrode 210, an upper electrode 200, and a ferroelectric layer 300 between the lower electrode 200 and the upper electrode 200. The capacitor 1 may be the capacitor D50 illustrated in FIG. 13, which has been described above, and thus, the description thereof will be omitted.

The field effect transistor 10 may include a substrate 100B and a gate electrode 12b provided on the substrate 100B. A gate insulating layer 12a may further be provided between the substrate 100B and the gate electrode 12b.

The substrate 100B may include a source 11a, a drain 11b, and a channel 11c electrically connected to the source 11a and the drain 11b. The source 11a may be electrically connected or in contact with one end of the channel 11c, and the drain 11b may be electrically connected or in contact with the other end of the channel 11c. The channel 11c may be defined as a substrate region between the source 11a and the drain 11b within the substrate 100B.

The substrate 100B may include a semiconductor material. The substrate 100B may include a semiconductor material, for example, Si, Ge, SiGe, SiC, GaAs, InAs, InP, etc. In addition, the substrate 100B may include a silicon on insulator (SOI) substrate.

The source 11a, the drain 11b, and the channel 11c may be formed by independently injecting impurities into different regions of the substrate 100B, and in this case, the source 11a, the channel 11c, and the drain 11b may include the substrate material as a base material. The source 11a and the drain 11b may include a conductive material, in this case, the source 11a and the drain 11b may include, for example, a metal, a metal compound, or a conductive polymer.

The channel 11c may also be implemented as a separate material layer (thin film) (not shown). In this case, for example, the channel 11c may include at least one of Si, Ge, SiGe, a Group III-V semiconductor, an oxide semiconductor, a nitride semiconductor, an oxynitride semiconductor, a two-dimensional material (2D material), a quantum dot, and an organic semiconductor. For example, the oxide semiconductor may include InGaZnO, etc., the two-dimensional material may include transition metal dichalcogenide (TMD) or graphene, and the quantum dots may include colloidal quantum dots (QDs) or nanocrystal structures.

The gate electrode 12b may be arranged to be spaced apart from the substrate 100B and to face the channel 11c on the substrate 100B. The gate electrode 12b may include a conductor, such as at least one of a metal, a metal nitride, a metal carbide, and polysilicon. For example, the metal may include at least one of Al, W, Mo, Ti, and Ta, and the metal nitride film may include at least one of a titanium nitride film (TiN film) and a tantalum nitride film (TaN film). The metal carbide may include at least one of a metal carbide doped with (or including) aluminum and silicon, and, as specific examples, may include TiAlC, TaAlC, TiSiC, or TaSiC.

The gate electrode 12b may have a stack structure in which a plurality of materials are stacked, for example, a stack structure of a metal nitride layer/metal layer such as TiN/Al, or a stack structure of a metal nitride layer/metal carbide layer/metal layer such as TiN/TiAlC/W. However, the materials mentioned above are only examples.

The gate insulating layer 12a may be further arranged between the substrate 100B and the gate electrode 12b. The gate insulating layer 12a may include a paraelectric material or a high-k dielectric material, and may have a dielectric constant of about 20 to 70.

The gate insulating layer 12a may include an insulator, such as silicon oxide, silicon nitride, aluminum oxide, hafnium oxide, zirconium oxide, etc., or may include a 2D insulator such as h-BN. For example, the gate insulating layer 12a may include SiO₂, SiNₓ, etc., and may also include HfO₂, HfSiO₄, La₂O₃, LaAlO₃, ZrO₂, hafnium zirconium oxide (HfZrO₂), ZrSiO₄, Ta₂O₅, TiO₂, SrTiO₃, Y₂O₃, Al₂O₃, PbSc_{0.5}Ta_{0.5}O₃, PbZnNbO₃, and the like. In addition, the gate insulating layer 12a may include a metal nitride oxide, such as AlON, ZrON, HON, LaON, YON, a silicate, such as ZrSiON, HfSION, YSiON, LaSiON, or an aluminate, such as ZrAlON, HfAlON, etc. In addition, the gate insulating layer 12a may include the ferroelectric layer described above. The gate insulating layer 12a may configure a gate stack together with the gate electrode 12b.

One of the electrodes 200 and 210 of the capacitor 1 and one of the source and drain 11a and 11b of the field effect transistor 10 may be electrically connected by a contact 20. Here, the contact 20 may include an appropriate conductive material, for example, tungsten, copper, aluminum, polysilicon, etc.

The arrangement of the capacitor 1 and the field effect transistor 10 may be variously modified. For example, the capacitor 1 may be arranged on the substrate 100B or may have a structure embedded in the substrate 100B. FIG. 15 illustrates the electronic device D60 including one capacitor 1 and one field effect transistor 10 but is not limited thereto. The electronic device may include a plurality of capacitors and a plurality of field effect transistors.

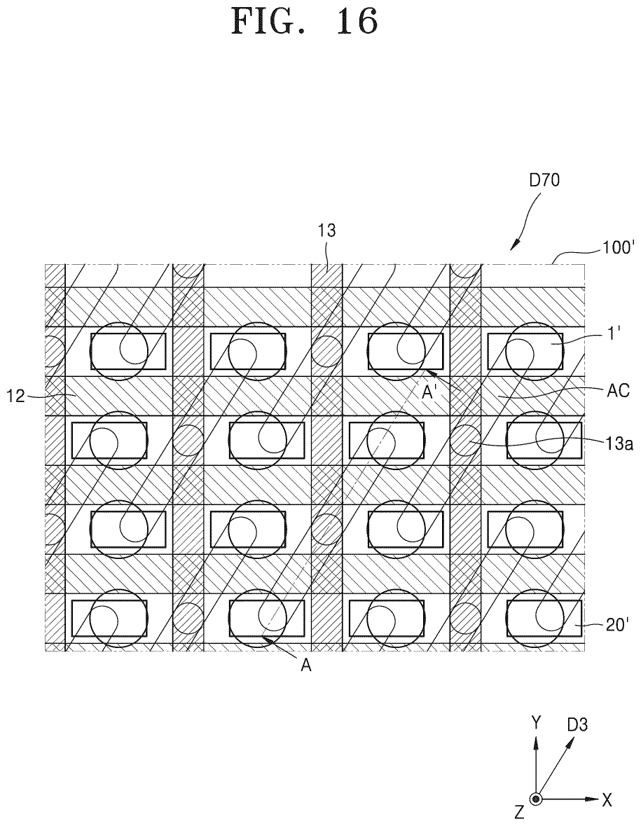

FIG. 16 is a diagram showing an electronic device D70 according to another embodiment.

Referring to FIG. 16, the electronic device D70 may include a structure in which a plurality of capacitors and a plurality of field effect transistors are repeatedly arranged. The electronic device D70 may include a substrate 100′ including a source, a drain, and a channel, a field effect transistor including a gate stack 12, a contact structure 20′ disposed on the substrate 100′ so as not to overlap with the gate stack 12, and a capacitor 1′ disposed on the contact structure 20′, and may further include a bit line structure 13 electrically connecting the plurality of field effect transistors.

FIG. 16 illustrates an example of a semiconductor device D10 in which both the contact structure 20′ and the capacitor 1′ are repeatedly arranged in the X direction and the Y direction, but is not limited thereto. For example, the contact structure 20′ may be arranged in the X direction and the Y direction, and the capacitor 1′ may be arranged in a hexagonal shape such as a honeycomb structure.

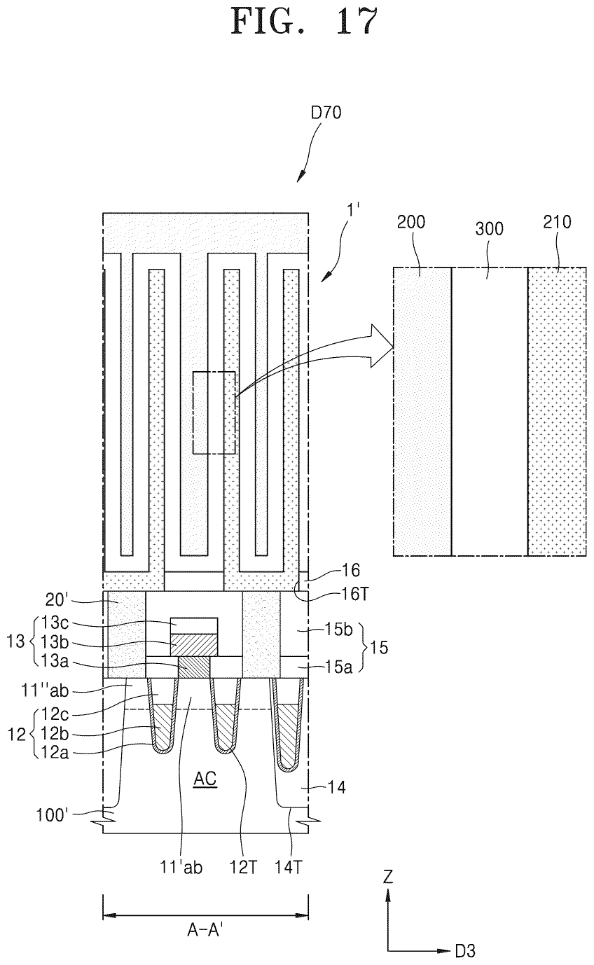

FIG. 17 is a cross-sectional view of the electronic device D70 taken along line A-A′ of FIG. 16.

Referring to FIG. 17, the substrate 100′ may have a shallow trench isolation (STI) structure including a device isolation film 14. The device isolation film 14 may be a single layer including one type of insulating film, or a multilayer including a combination of two or more types of insulating films. The device isolation film 14 may include a device isolation trench 14T in the substrate 100′, and the device isolation trench 14T may be filled with an insulating material. The insulating material may include, but is not limited to, at least one of fluoride silicate glass (FSG), undoped silicate glass (USG), boro-phospho-silicate glass (BPSG), phospho-silicate glass (PSG), flowable oxide (FOX), plasma enhanced tetra-ethyl-ortho-silicate (PE-TEOS), and/or tonen silazene (TOSZ).

The substrate 100′ may further include an active region AC defined by the device isolation film 14 and a gate line trench 12T arranged to be parallel to an upper surface of the substrate 100′ and extending in the X direction. The active region AC may have a relatively long island shape having a short axis and a long axis. The long axis of the active region AC may be arranged in the D3 direction parallel to the upper surface of the substrate 100′, as illustrated in FIG. 15.

The gate line trench 12T may be arranged to intersect the active region AC at a predetermined depth from the upper surface of the substrate 100′ or within the active region AC. The gate line trench 12T may also be arranged inside the device isolation trench 14T, and the gate line trench 12T inside the device isolation trench 14T may have a bottom surface that is lower than the gate line trench 12T of the active region AC. A first source/drain 11′ab and a second source/drain 11″ab may be arranged on an upper portion of the active region AC located on both sides of the gate line trench 12T.

The gate stack 12 may be arranged inside the gate line trench 12T. Specifically, a gate insulating layer 12a, a gate electrode 12b, and a gate capping layer 12c may be sequentially arranged inside the gate line trench 12T. The gate insulating layer 12a and the gate electrode 12b may refer to the content described above, and the gate capping layer 12c may include an insulator, such as at least one of silicon oxide, silicon oxynitride, and silicon nitride. The gate capping layer 12c may be arranged on the gate electrode 12b to fill the remaining portion of the gate line trench 12T.

The bit line structure 13 may be arranged on the first source/drain 11′ab. The bit line structure 13 may be arranged to be parallel to the upper surface of the substrate 100′ and extend in the Y direction. The bit line structure 13 may be electrically connected to the first source/drain 11′ab and may sequentially include a bit line contact 13a, a bit line 13b, and a bit line capping layer 13c on the substrate. For example, the bit line contact 13a may include polysilicon, the bit line 13b may include a metal material, and the bit line capping layer 13c may include an insulating material such as silicon nitride or silicon oxynitride.

FIG. 17 illustrates an example in which the bit line contact 13a has a bottom surface at the same level as the upper surface of the substrate 100′, but the bit line contact 13a may extend into a recess (not shown) formed at a predetermined depth from the upper surface of the substrate 100′ so that the bottom surface of the bit line contact 13a is lower than the upper surface of the substrate 100′.

The bit line structure 13 may further include a bit line intermediate layer (not shown) between the bit line contact 13a and the bit line 13b. The bit line intermediate layer may include a metal silicide such as tungsten silicide, or a metal nitride such as tungsten nitride. In addition, a bit line spacer (not shown) may further be formed on a sidewall of the bit line structure 13. The bit line spacer may have a single-layer structure or a multi-layer structure and may include an insulating material such as silicon oxide, silicon oxynitride, or silicon nitride. In addition, the bit line spacer may further include an air space (not shown).

The contact structure 20′ may be disposed on the second source/drain 11″ab. The contact structure 20′ and the bit line structure 13 may be respectively arranged on different source/drains on the substrate. The contact structure 20′ may have a structure in which a lower contact pattern (not shown), a metal silicide layer (not shown), and an upper contact pattern (not shown) are sequentially stacked on the second source/drain 11″ab. The contact structure 20′ may further include a barrier layer (not shown) surrounding a side surface and a bottom surface of the upper contact pattern. For example, the lower contact pattern may include polysilicon, the upper contact pattern may include a metal material, and the barrier layer may include a conductive metal nitride.

The capacitor 1′ may be electrically connected to the contact structure 20′ and arranged on the substrate 100′. Specifically, the capacitor 1′ may include a lower electrode 210 electrically connected to the contact structure 20′, a ferroelectric layer 300 disposed on the lower electrode 210, and an upper electrode 200 disposed on the ferroelectric layer 300. The ferroelectric layer 300 may be disposed on the lower electrode 210 so as to be parallel to a surface of the lower electrode 200. Because the lower electrode 210, the ferroelectric layer 300, and the upper electrode 200 of the capacitor 1′ have been described above, the description thereof will not be repeated.

An interlayer insulating layer 15 may be further arranged between the capacitor 1′ and the substrate 100′. The interlayer insulating layer 15 may be arranged in a space between the capacitor 1′ and the substrate 100′ where no other structure is arranged. Specifically, the interlayer insulating layer 15 may be arranged to cover wiring and/or electrode structures such as the bit line structures 13, the contact structures 20′, and the gate stacks 12 on the substrate. For example, the interlayer insulating layer 15 may surround walls of the contact structure 20′. The interlayer insulating layer 15 may include a first interlayer insulating layer 15a surrounding the bit line contact 13a and a second interlayer insulating layer 15b covering side surfaces and/or upper surfaces of the bit line 13b and the bit line capping layer 13c.

The lower electrode 210 of the capacitor 1′ may be disposed on the interlayer insulating layer 15, specifically, on the second interlayer insulating layer 15b. In addition, when a plurality of capacitors 1′ are provided, bottom surfaces of the plurality of lower electrodes 210 may be separated by an etch stop layer 16. In other words, the etching stop layer 16 may include an opening 16T, and the bottom surface of the lower electrode 210 of the capacitor 1′ may be placed within the opening 16T. The lower electrode 210 may have a cylinder shape or a cup shape with a bottom closed as shown in FIG. 17.

The semiconductor device D according to the embodiments described above and the electronic device including the same may be applied to various application fields. For example, the electronic devices or electronic apparatuses according to the embodiments may be applied as a logic device or a memory device. The electronic devices and the electronic apparatuses according to the embodiments may be used for arithmetic operations, program execution, temporary data maintenance, etc. in devices such as mobile devices, computers, laptops, sensors, network devices, and neuromorphic devices. In addition, the electronic devices and the electronic apparatuses according to the embodiments may be useful in devices with a large amount of data transmission and in which data transmission is performed continuously.

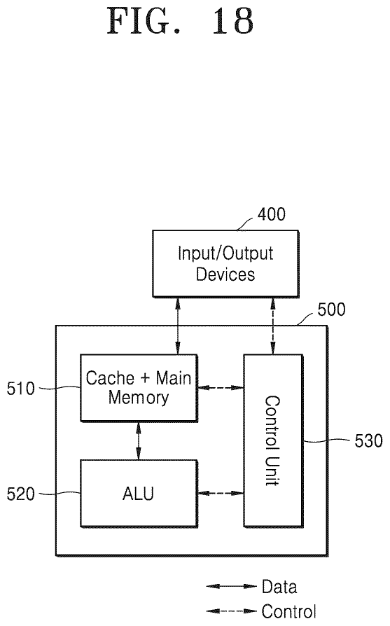

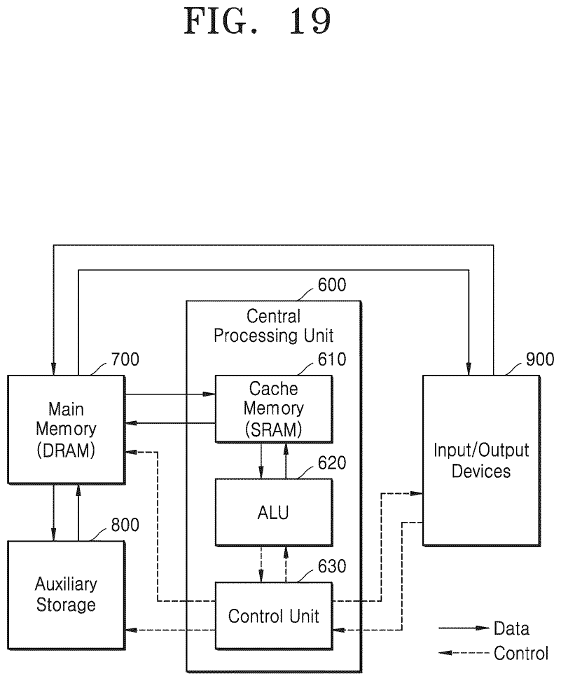

FIGS. 18 and 19 are conceptual diagrams schematically showing a device architecture 500 that may be applied to a device, according to at least one embodiment.

Referring to FIG. 18, the electronic device architecture 500 may include a memory unit 510, an arithmetic logic unit (ALU) 520, and a control unit 530. The memory unit 510, the ALU 520, and the control unit 530 may be electrically connected. For example, the electronic device architecture 500 may be implemented as a single chip including the memory unit 510, the ALU 520, and the control unit 530.

The memory unit 510, the ALU 520, and the control unit 530 may be interconnected with metal lines on-chip and may communicate directly. The memory unit 510, the ALU 520, and the control unit 530 may be monolithically integrated on a single substrate to form a single chip. An input/output device 400 may be connected to the electronic device architecture (chip) 500 and may be configured to received inputs and/or provide outputs to, e.g., a user and/or companion device. In addition, the memory unit 510 may include both a main memory and a cache memory. This electronic device architecture (chip) 500 may be an on-chip memory processing unit. The memory unit 510, the ALU 520, or the control unit 530 may each include the electronic devices described above.

Referring to FIG. 19, a cache memory 610, an ALU 620, and a control unit 630 may constitute a central processing unit (CPU) 600, and the cache memory (610) may include a static random access memory (SRAM). Separately from the CPU 600, a main memory 700 and an auxiliary storage 800 may be provided. The main memory 700 may be a dynamic random-access memory (DRAM) and may include the semiconductor devices D described above. In some cases, the electronic device architecture may be implemented in a form in which computing unit devices and memory unit devices are adjacent to each other in a single chip without distinction of sub-units.

A ferroelectric layer of the disclosure may stably maintain an orthorhombic crystal structure of oIV phase (space group: Pmn21) because lattice volume has been expanded using an expansion ratio between a dopant and the base material.

A semiconductor device of the disclosure includes a ferroelectric layer having an orthorhombic crystal structure of oIV phase (space group: Pmn21), and thus may have a high polarization value and a low polarization switching energy barrier.

The semiconductor device including the ferroelectric layer having the above-described characteristics may have improved operation reliability.

However, the effects of the disclosure are not limited to the above descriptions.

Although the semiconductor devices and electronic devices including the same have been illustrated and described above, the disclosure is not limited to the specific embodiments described above, and various modifications may be made by a person having ordinary knowledge in the technical field to which the disclosure pertains without departing from the gist of the disclosure claimed in the claims, and such modifications should not be understood individually from the technical idea or prospect of the disclosure.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a semiconductor layer;
an electrode on the semiconductor layer; and
a ferroelectric layer electrically isolating the semiconductor layer from the electrode, the ferroelectric layer including an orthorhombic crystal structure of an oIV phase (space group: Pmn21) and doped with a dopant at 2.8 at % or more, the dopant having an ionic radius larger than that of at least one of a hafnium ion or an oxygen ion.

2. The semiconductor device of claim 1, wherein the dopant expands a lattice volume of the orthorhombic crystal structure of the oIV phase (space group: Pmn21).

3. The semiconductor device of claim 1, wherein the dopant includes elements having a same ionic valence as the oxygen ion and a larger ionic radius than the oxygen ion.

4. The semiconductor device of claim 1, wherein the dopant includes at least one of sulfur (S), selenium (Se), or tellurium (Te).

5. The semiconductor device of claim 1, wherein the dopant includes an element having a same ionic valence as the hafnium ion and a larger ionic radius than the hafnium ion.

6. The semiconductor device of claim 1, wherein the dopant includes cerium (Ce).

7. The semiconductor device of claim 1, wherein the dopant is within a range of 2.8 at % to 10 at %.

8. The semiconductor device of claim 1, wherein the orthorhombic crystal structure of the oIV phase (space group: Pmn21) has an interplanar distance (d-spacing) of 3.05 Å or more in an out-of-plane direction to a surface of the semiconductor layer.

9. The semiconductor device of claim 1, wherein the ferroelectric layer further includes an orthorhombic crystal structure of an oIII phase.

10. The semiconductor device of claim 1, wherein, among the orthorhombic crystal structure of the oIV phase (space group: Pmn21), an interplanar distance (d-spacing) in an out-of-plane direction to a surface of the semiconductor layer is larger than an interplanar distance (d-spacing) of an orthorhombic crystal structure of an oIII phase.

11. The semiconductor device of claim 1, wherein, among a crystal structure of the ferroelectric layer, the orthorhombic crystal structure of the oIV phase (space group: Pmn21) is dominant.

12. The semiconductor device of claim 11, wherein, among the crystal structure of the ferroelectric layer, the orthorhombic crystal structure of the oIV phase (space group: Pmn21) is 50% or more.

13. The semiconductor device of claim 1, wherein the ferroelectric layer includes at least one of hafnium oxide or hafnium zirconium oxide.

14. The semiconductor device of claim 1, wherein a thickness of the ferroelectric layer is 2 nanometers (nm) or more.

15. The semiconductor device of claim 1, wherein a thickness of the ferroelectric layer is 10 nanometers (nm) or less.

16. The semiconductor device of claim 1, wherein the semiconductor layer includes:
a channel overlapping the ferroelectric layer in a thickness direction of the ferroelectric layer; and
a source region and a drain region spaced apart from each other with the channel therebetween.

17. The semiconductor device of claim 1, further comprising:
a paraelectric layer between the ferroelectric layer and the semiconductor layer.

18. The semiconductor device of claim 17, wherein the paraelectric layer includes at least one of aluminum oxide (Al₂O₃), lanthanum oxide (La₂O₃), yttrium oxide (Y₂O₃), and silicon oxide (SiO₂).

19. The semiconductor device of claim 1, further comprising:
a conductive material between the semiconductor layer and the ferroelectric layer.

20. The semiconductor device of claim 1, wherein the semiconductor layer includes at least one component of a transistor.
